(19) United States
(12) Patent Application Publication
(10) Pub. No.: US 2014/0252779 A1
(43) Pub. Date: Sep. 11, 2014

(54) Locking Arrangement

(71) Applicant: NOKIA CORPORATION, Espoo (FI)

(72) Inventor: Heidi Mirjam TOIVANEN, Tampere (FI)

(73) Assignee: Nokia Corporation, Espoo (FI)

(21) Appl. No.: 13/792,607

(22) Filed: Mar. 11, 2013

(51) Int. Cl. H05K 5/02

(52) U.S. Cl. CPC H05K 5/0221
USPC 292/155

(57) ABSTRACT

In accordance with an example embodiment of the present invention, there is provided a locking arrangement configured to attach to each other a body part of an electronic device and a cover part of the electronic device. The locking arrangement includes an elongated locking part configured to be mounted inside the body part. The locking part is configured to be movable between an open position and a closed position inside the body part and the locking part extends along most of the length of one edge of the body part. In the closed position the locking part engages the cover part thereby coupling the cover part and the body part together.

### TECHNICAL FIELD

The present application generally relates to a locking arrangement for a portable electronic device such as a mobile phone, a smart phone, a tablet, or other electronic device. In particular, though not exclusively, the present application relates to a locking arrangement for attaching a display module to a body part of a portable electronic device.

### BACKGROUND

Portable or handheld electronic devices such as mobile phones, smart phones, tablets, or other electronic devices often comprise two or more parts or modules that are mounted together. There may be for example a unibody chassis and a display module that are attached to each other. For example for repair purposes the display, module needs to be removably assembled into the unibody chassis.

### SUMMARY

Various aspects of examples of the invention are set out in the claims.

According to a first example aspect of the present invention, there is provided an apparatus comprising
a locking arrangement configured to attach to each other a body part of an electronic device and a cover part of said electronic device, wherein said locking arrangement comprises
an elongated locking part configured to be mounted inside said body part, wherein
said locking part is configured to be movable between an open position and a closed position inside said body part,
said locking part extends along most of the length of one edge of the body part, and wherein in said closed position said locking part engages said cover part thereby coupling said cover part and said body part together.

According to a second example aspect of the present invention, an apparatus, such as a portable electronic device or an electronic device, comprising
a body part,
a cover part, and
a locking arrangement configured to attach to each other said body part and said cover part, wherein said locking arrangement comprises
an elongated locking part mounted inside said body part, wherein
said locking part is configured to be movable between an open position and a closed position inside said body part,
said locking part extends along most of the length of one edge of the body part, and wherein in said closed position said locking part engages said cover part thereby coupling said cover part and said body part together.

According to a third example aspect of the present invention, there is provided a method comprising
mounting a locking part inside a body part of an electronic device, wherein said locking part is movable between an open position and a closed position inside the body part; and said locking part extends along most of the length of one edge of the body part;
fitting a cover part onto the body part while the locking part is in the open position, the cover part hiding the locking part inside the body part; and
moving said locking part into the closed position thereby engaging said cover part and coupling said cover part and said body part together

Different non-binding example aspects and embodiments of the present invention have been illustrated in the foregoing. The embodiments in the foregoing are used merely to explain selected aspects or steps that may be utilized in implementations of the present invention. Some embodiments may be presented only with reference to certain example aspects of the invention. It should be appreciated that corresponding embodiments may apply to other example aspects as well.

### BRIEF DESCRIPTION OF THE DRAWINGS

For a more complete understanding of example embodiments of the present invention, reference is now made to the following descriptions taken in connection with the accompanying drawings in which:

FIG. 1a shows a schematic front view of a first apparatus according to an example embodiment of the invention;

FIG. 1b shows a schematic back view of a first apparatus according to an example embodiment of the invention;

FIG. 2 is a flow diagram showing assembly process according to an example embodiment of the invention;

FIG. 3a shows a schematic view of a locking part of an example embodiment of the invention;

FIG. 3b shows another schematic view of a locking part of an example embodiment of the invention;

FIG. 3c shows a schematic view of a detail of a locking part of an example embodiment of the invention;

FIG. 3d shows a schematic view of a display module of an example embodiment of the invention;

FIG. 3e shows a schematic view of a body part of an example embodiment of the invention;

FIG. 3f shows a partial cross sectional view illustrating mounting of a locking part into a body part in an example embodiment of the invention;

FIG. 3g shows a partial schematic view illustrating mounting of a locking part into a body part in an example embodiment of the invention;

FIG. 4a illustrates cross section of a locking arrangement of an example embodiment of the invention in an open position;

FIG. 4b illustrates cross section of a locking arrangement of an example embodiment of the invention in a closed position;

FIG. 4c illustrates cross section of a locking arrangement of an example embodiment of the invention in an open position;

FIG. 4d illustrates cross section of a locking arrangement of an example embodiment of the invention in a closed position.

### DETAILED DESCRIPTION OF THE DRAWINGS

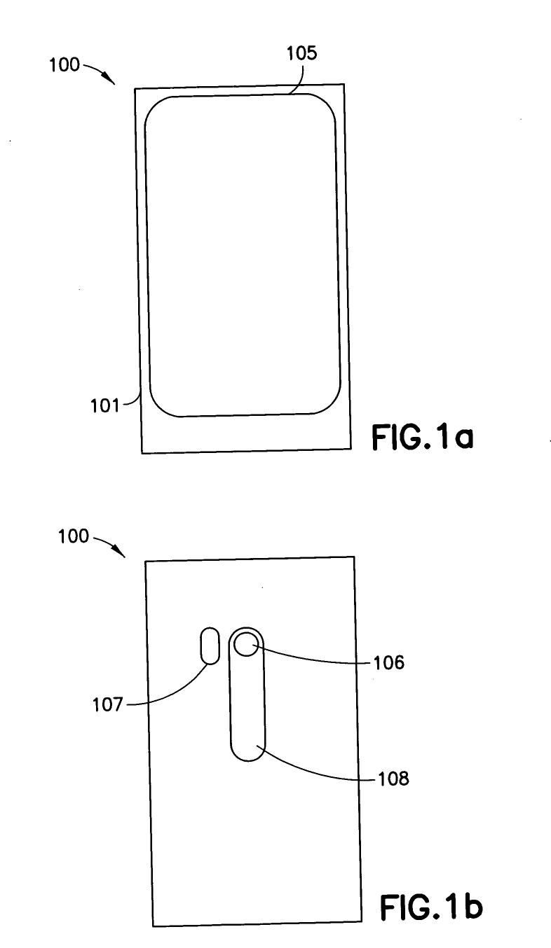

An example embodiment of the present invention and its potential advantages are understood by referring to FIGS. 1a through 4d of the drawings. In this document, like reference signs denote like parts or steps.

FIG. 1a shows a schematic front view of an apparatus 100 according to an example embodiment of the invention. The apparatus 100 is for example a mobile phone, a smart phone, a tablet computer or an e-book reader and/or other portable electronic device. The apparatus 100 comprises a display 105 and a body part 101. In an example embodiment, the display 105 is a touch sensitive display. The touch sensitive display 105 comprises, in an example embodiment, a touch sensor for detecting the touch of the user on or in proximity thereof. In an example embodiment, the touch sensor comprises a resistive, a surface acoustic wave, a capacitive—such as a surface capacitance, a projected capacitance, a mutual capacitance, or self-capacitance—an infrared, an optical, a dispersive signal and/or acoustic pulse recognition touch sensor or an array thereof. In an example embodiment, the apparatus 100 comprises, in addition to the display 105, other user interface elements such as buttons, hardware or soft buttons or further display units. Furthermore, the apparatus 100, in a further example embodiment, comprises further elements (not shown), such as microphones, speakers, sensors or detectors and/or camera units.

FIG. 1b shows a schematic back view of the apparatus 100 according to an example embodiment of the invention. In an example embodiment the apparatus comprises a lens 106 of a camera unit, a flash element 107, such as a led and/or xenon flash, and/or a decorative or protective element 108. Furthermore, the apparatus 100, in a further example embodiment, comprises further elements that are not shown.

An example embodiment of the invention provides a locking arrangement for an electronic device such as the apparatus 100 of FIGS. 1a and 1b. The locking arrangement provides locking between a body part and a cover part of the electronic device. In an example embodiment the body part is a unibody chassis. In an example embodiment the cover part is a display module, such as the display 105 of FIGS. 1a and 1b. An example embodiment of the invention provides a mechanism for removably attaching a unibody chassis of a device to a display module thereby enabling access to the interior of the device for example for repair purposes.

In an example embodiment of the invention the locking arrangement comprises an elongated locking part configured to be mounted inside the body part and the locking part is movable between an open position and a closed position inside the body part. The locking part extends along most of the length of one edge of the body part, and in the closed position the locking part engages the cover part so that the cover part and the body part are coupled together along the edge of the body part. In an example embodiment of the invention the locking part couples the cover part to the body part at a plurality of points along the length of the locking part. In an example embodiment of the invention the locking part couples the cover part to the body part along most of the length of the locking part. In an example embodiment of the invention the locking part couples the cover part to the body part along most of the length of one edge of the body part. In an example embodiment the term most of the length refers to more than 50% of the length. In an example embodiment the locking part provides coupling along full length of the locking part or full length of one edge of the body part.

In an example embodiment of the invention the locking arrangement comprises at least one guiding member configured to guide movement of the locking part inside the body part and at least one engagement member configured to engage the cover part with the locking part when the locking part is in the closed position. In an example embodiment of the invention the guiding members comprise one or more of the following or a combination thereof: a rib, a snap, a groove, a guiding surface, a protrusion and a groove configured to receive the protrusion. In an example embodiment of the invention the guiding members comprise a plastic frame configured for attaching the locking part into the body part. In an example embodiment of the invention the engagement members comprise one or more of the following or a combination thereof: a protruding hook like structure and a hole/opening/aperture configured to receive the hook like structure, hook like protrusions configured to engage with each other, a lug, a loop. In an example embodiment of the invention the cover part comprises hook like protrusions and the locking member comprises openings configured to receive the hook like protrusions. The hook like protrusions and the openings provide the engagement between the cover part and the body part in the closed position. Some example structures are discussed in more detail below.

In an example embodiment of the invention the locking part comprises a movement member configured to move the locking part inside the body part. In an example embodiment of the invention the movement member is a screw. In an example embodiment of the invention the movement member is a bolt. In an example embodiment of the invention the movement member is a hidden screw that is not visible from the exterior of the device. In an example, the hidden screw resides inside a closable opening in device body. The closable opening may be for example a sim (subscriber identity module) card tray aperture or a memory card opening. In this way the locking arrangement is non-visible from the exterior of the device. In an alternative embodiment the movement member is fully or partially visible and arranged on a surface of the body part or in a recess of the body part.

In an example embodiment of the invention movement of the locking part inside the body part is a linear movement along the length of the locking part. In an example embodiment of the invention movement of the locking part inside the body part is a twisting movement about axis of the locking part.

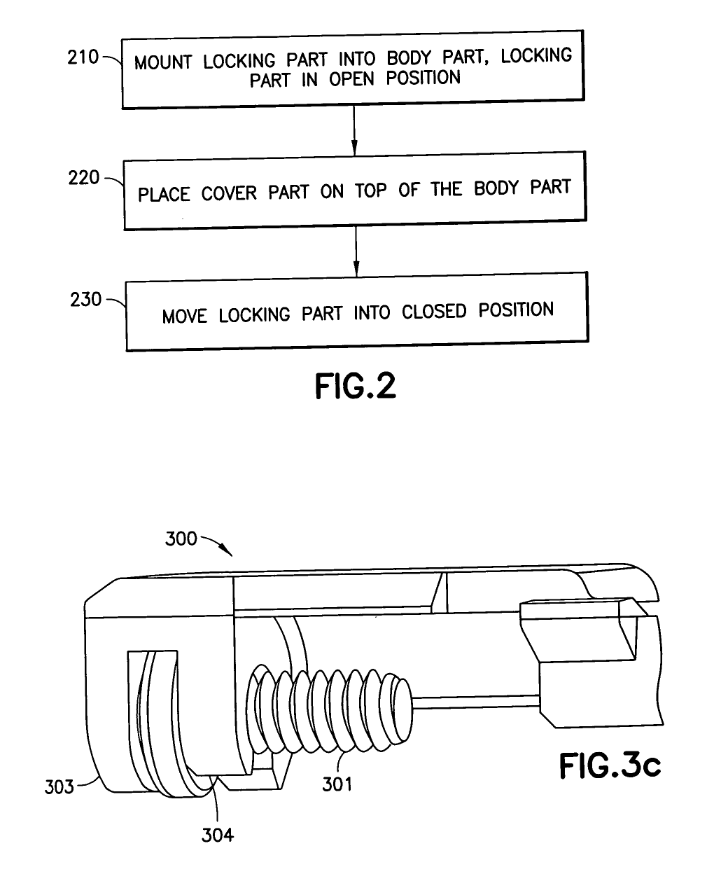

FIG. 2 is a flow diagram showing assembly process according to an example embodiment of the invention.

In phase 210, a locking part is mounted into a body part of a portable electronic device. In this phase the locking part is in an open position. In an example embodiment, the locking part is mounted inside the body part. In an example embodiment, the body part comprises ribs and a plastic frame glued into the body part. In such embodiment one side of the locking part is placed under the ribs in the body part and the other side of the locking part is placed under hooks in the plastic frame. It needs to be understood that there are also other embodiments in which details of the mounting of the locking part are different from this example.

In phase 220, a cover part is placed on top of the body part. In an example embodiment, one side of the cover part comprises snaps/hooks and these snaps/hooks are placed under ribs in the body part. Other side of the cover part is pressed on top of the locking part. In an example embodiment, the cover part hides the locking part inside the electronic device.

In phase 230, the locking part is moved into a closed position thereby engaging with the cover part and attaching the cover part into the body part. In an example embodiment, the locking part comprises a preassembled screw and the locking part is moved by screwing the screw in or out. In an example embodiment screwing in the screw pushes the locking part in into the closed position and tightens gaps between the cover part and the body part thereby closing the electronic device. Unscrewing the screw pulls the locking part out back to the open position thereby enabling opening the electronic device.

In an example embodiment the body part comprises an opening, such as a sim (subscriber identity module) door opening or memory card opening and the screw of the locking part is mounted such that it is operable through the opening. In an example embodiment the opening in the body part comprises a door for closing the opening thereby hiding the screw. In this way the locking part is not visible outside the electronic apparatus.

FIG. 2 shows a phase in which the locking part is moved into a closed position. It is understood that likewise the locking part is movable from the closed position back to the open position thereby enabling releasing the cover part and enabling detaching the cover part from the body part and opening the electronic device.

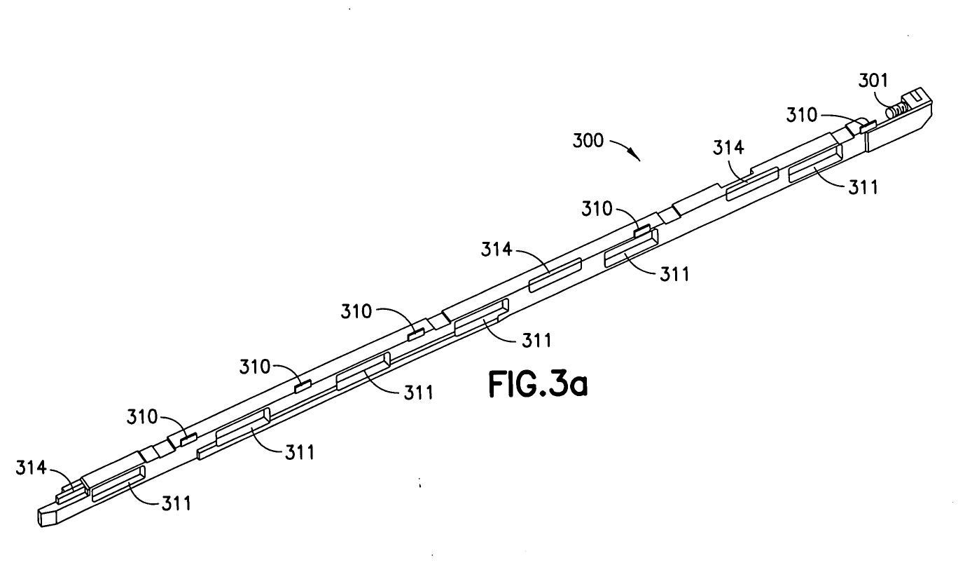

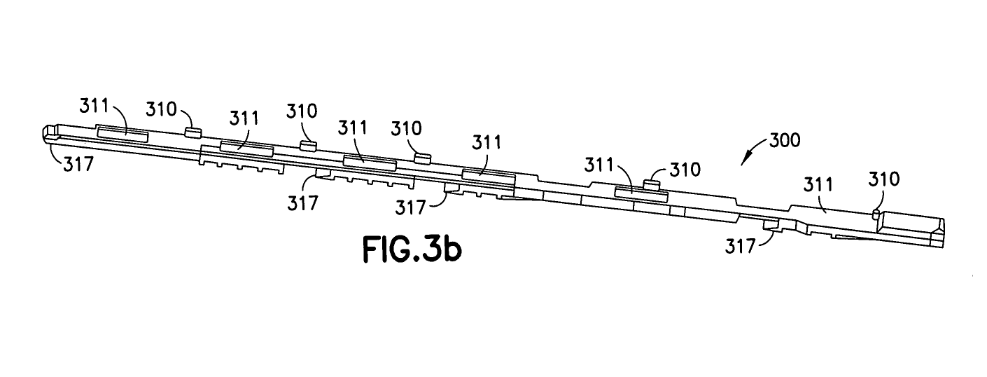

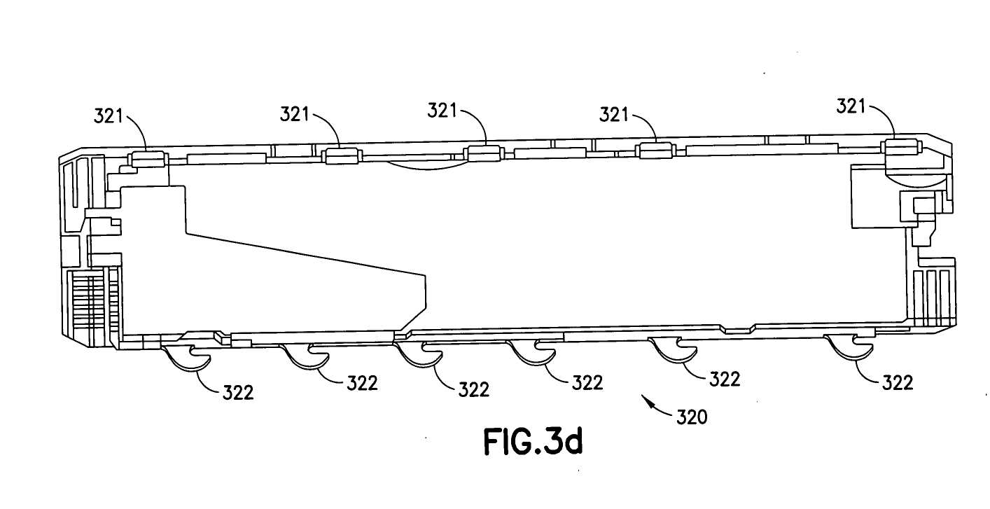

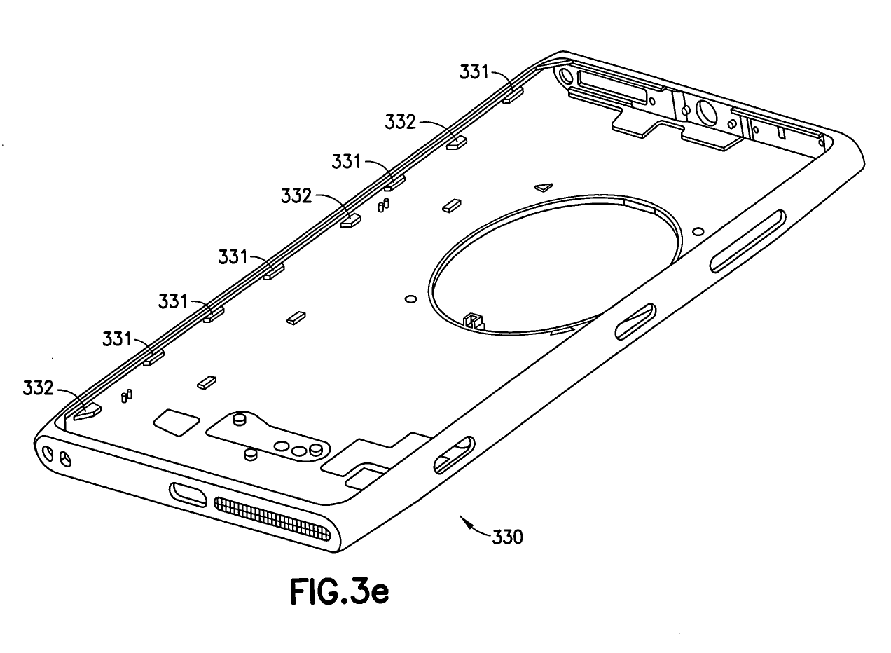

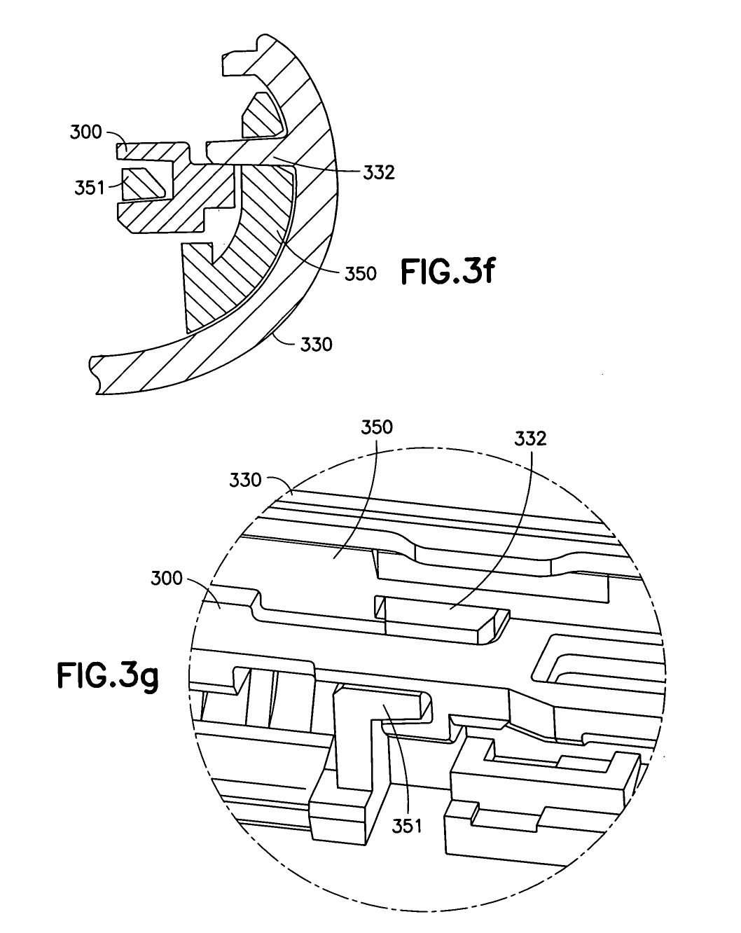

FIG. 3a shows a schematic view of a locking part 300 of an example embodiment of the invention. The locking part 300 has an elongated form and comprises guiding members 310, 314 openings 311 and a preassembled screw 301. In this example the guiding members include ribs 310 and surfaces 314. It is possible that the locking part comprises also other guiding members in addition to these. Furthermore it is possible that the locking part 300 comprises only the ribs 310 or the surfaces 314. In other examples other guiding member structures are possible. When the locking part 300 is mounted into a body part of an electronic apparatus, the guiding members 310 are configured to interact with guiding members of the body part such that the guiding members 310, 314 of the locking part 300 and the guiding members of the body part allow certain movement of the locking part 300 inside the body part. The openings 311 are configured to receive protrusions of a cover part when the locking part 300 is in an open position in a body part and to lock the cover part to the body part when the locking part 300 is in a closed position in the body part. The screw 301 is configured to enable movement of the locking part 300 when the locking part 300 is mounted into a body part of an electronic apparatus.

FIG. 3b shows a schematic view of a locking part 300 of an example embodiment of the invention. The locking part 300 has an elongated form and comprises guiding members 310, 317 openings 311. In this example the guiding members include ribs 310 and surfaces 317. It is possible that the locking part 300 comprises also other guiding members in addition to these. Furthermore it is possible that the locking part 300 comprises only the ribs 310 or the surfaces 317. When the locking part 300 is mounted into a body part of an electronic apparatus, the guiding members 310 are configured to interact with guiding members of the body part such that the guiding members 310, 317 of the locking part 300 and the guiding members of the body part allow certain movement of the locking part 300 inside the body part. The openings 311 are configured to receive protrusions of a cover part when the locking part 300 is in an open position in a body part and to lock the cover part to the body part when the locking part 300 is in a closed position in the body part. In an example embodiment FIGS. 3a and 3b show different sides of the same locking part.

FIG. 3c shows a partial schematic view of a detail of a locking part 300 of an example embodiment of the invention. FIG. 3c shows structure of the locking part 300 near the screw 301 according to an example embodiment. The locking part 300 extends to both sides 303 and 304 of the screw 301. By having material of the locking part on both sides of the screw 301 one enables that the locking part moves in both directions, that is, screwing in the screw pushes the locking part in and screwing out the screw pulls the locking part out.

FIG. 3d shows a schematic view of a display module 320 of an example embodiment of the invention. The display module 320 comprises snaps/hooks 321 on one side of the display module 320 and hook like protrusions 322 on the other side of the display module 320. When the display module 320 is fitted into a body part of an electronic device, the snaps/hooks 321 are configured to be placed under ribs in the body part and the protrusions 322 are configured to be placed into openings in a locking part mounted inside the body part.

FIG. 3e shows a schematic view of a body part 330 of an example embodiment of the invention. The body part 330 comprises ribs 331, 332 for attaching a locking part into the body part 330.

FIG. 3f shows a partial cross sectional view illustrating mounting of a locking part 300 into a body part 330 in an example embodiment of the invention. The body part 330 comprises a rib 332 and a plastic frame 350 fitted into the body part 330. The plastic frame comprises a hook 351. The locking part 300 is mounted into the body part 330 so that one side of the locking part 300 fits under the rib 332 and other side of the locking part 300 fits under the hook 351 of the plastic frame 350. The hook 351 and the rib 332 guide movement of the locking part 300 inside the body part 330.

FIG. 3g shows a partial schematic view illustrating mounting of a locking part 300 into a body part 330 in an example embodiment of the invention. The body part 330 comprises a rib 332 and a plastic frame 350 fitted into the body part 330. The plastic frame comprises a hook 351. The locking part 300 is mounted into the body part 330 so that one side of the locking part 300 fits under the rib 332 and other side of the locking part 300 fits under the hook 351 of the plastic frame 350. The hook 351 and the rib 332 guide movement of the locking part 300 inside the body part 330.

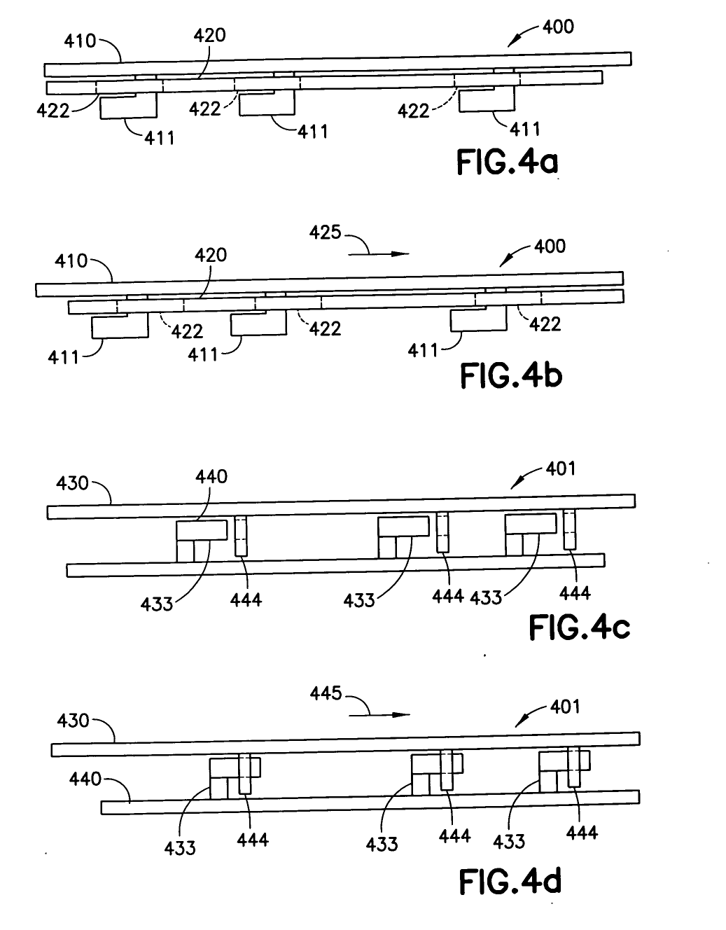

FIG. 4a illustrates cross section of a locking arrangement 400 of an example embodiment of the invention in an open position. The locking arrangement 400 comprises a cover part 410 and a locking part 420. The body part is not shown in this figure for the sake of clarity. The cover part 410 comprises a plurality of hook like protrusions 411 and the locking part 420 comprises a plurality of openings 422. In FIG. 4a the locking part 420 is in open position and the protrusions 411 of the cover part 410 fit into the openings 422 of the locking part 420.

FIG. 4b illustrates cross section of a locking arrangement of FIG. 4a in a closed position. Now the locking part 420 has been moved in the direction of arrow 425 and the locking part 420 is in closed position. The locking part 420 engages with the protrusions 411 of the cover part 410 thereby connecting the cover part 410 to the locking part 420 (and to a body part inside which the locking part is mounted).

FIG. 4c illustrates cross section of a locking arrangement 401 of an example embodiment of the invention in an open position. The locking arrangement 401 comprises a cover part 430 and a locking part 440. The body part is not shown in this figure for the sake of clarity. The cover part 430 comprises a plurality of protrusions 444 that comprise openings and the locking part 440 comprises a plurality of hook like protrusions 433. In FIG. 4c the locking part 440 is in open position and the protrusions 444 of the cover part 430 and the protrusions 433 of the locking part 440 fit next to each other.

FIG. 4d illustrates cross section of a locking arrangement of FIG. 4c in a closed position. Now the locking part 440 has been moved in the direction of arrow 445 and the locking part 440 is in closed position. The protrusions 433 of the locking part 440 fit through the openings in the protrusions 444 of the cover part 430 thereby connecting the cover part 430 to the locking part 440 (and to a body part inside which the locking part is mounted).

It must be noted that FIGS. 4a-4d illustrate some example structures of engagement members in the cover part and locking part. Also other structures suitable for providing engagement between the cover part and the locking part are possible.

In FIGS. 4a-4d the movement of the locking part is longitudinal movement. In an alternative example embodiment the locking part is turned about it's axis from an open position to a closed position and vice versa.

Without in any way limiting the scope, interpretation, or application of the claims appearing below, a technical effect of one or more of the example embodiments disclosed herein is that the locking arrangement provides multiple contact points between a body part and a cover part of the electronic device with one locking part. In this way it is possible to provide better connection between the body part and the cover part than for example when using simple screws for attaching a cover part to a body part. Since multiple connection points are provided by one locking part it is possible to achieve simple assembly and reassembly.

Another technical effect of one or more of the example embodiments disclosed herein is that the locking arrangement is not observable to the user of the device. Another technical effect of one or more of the example embodiments disclosed herein is that no visible screws are required on the device. Another technical effect of one or more of the example embodiments disclosed herein is capability to control functional and visual gaps between different parts of the device. Another technical effect of one or more of the example embodiments disclosed herein is capability to improve making the device waterproof, because the locking arrangement does not require any additional holes in the device cover.

Yet another technical effect of one or more of the example embodiments disclosed herein is possibility to improve antenna performance. It is possible to get metal parts (e.g. screws) away from device's antenna area. Another technical effect of one or more of the example embodiments disclosed herein is possibility to improve audio performance. It is possible to get more volume for speaker's back/front cavities as no screws are needed. Another technical effect of one or more of the example embodiments disclosed herein is possibility to use wider choice of materials. Different materials may be suitable for the locking part, depending on product possibilities.

If desired, the different functions discussed herein may be performed in a different order and/or concurrently with each other. Furthermore, if desired, one or more of the before-described functions and structures may be optional or may be combined.

Although various aspects of the invention are set out in the independent claims, other aspects of the invention comprise other combinations of features from the described embodiments and/or the dependent claims with the features of the independent claims, and not solely the combinations explicitly set out in the claims.

It is also noted herein that while the foregoing describes example embodiments of the invention, these descriptions should not be viewed in a limiting sense. Rather, there are several variations and modifications which may be made without departing from the scope of the present invention as defined in the appended claims.

What is claimed is:

1. An apparatus, comprising:
a locking arrangement configured to attach to each other a body part of an electronic device and a cover part of said electronic device, wherein said locking arrangement comprises
an elongated locking part configured to be mounted inside said body part, wherein
said locking part is configured to be movable between an open position and a closed position inside said body part,
said locking part extends along most of the length of one edge of the body part, and wherein in said closed position said locking part engages said cover part thereby coupling said cover part and said body part together.

2. The apparatus of claim 1, wherein in said closed position said locking part engages said cover part at a plurality of points along the length of said locking part.

3. The apparatus of claim 1, wherein in said closed position said locking part engages said cover part along most of the length of said locking part.

4. The apparatus of claim 1, wherein in said closed position said locking part engages said cover part along most of the length of one edge of said body part.

5. The apparatus of claim 1, wherein said locking arrangement comprises at least one guiding member configured to guide movement of the locking part inside said body part and at least one engagement member configured to engage said cover part with said locking part when said locking part is in said closed position.

6. The apparatus of claim 1, wherein said electronic device is a portable electronic device.

7. An electronic device, comprising:
a body part,
a cover part, and
a locking arrangement configured to attach to each other said body part and said cover part, wherein said locking arrangement comprises
an elongated locking part mounted inside said body part, wherein
said locking part is configured to be movable between an open position and a closed position inside said body part,
said locking part extends along most of the length of one edge of the body part, and wherein in said closed position said locking part engages said cover part thereby coupling said cover part and said body part together.

8. The electronic device of claim 7, wherein in said closed position said locking part engages said cover part along most of the length of one edge of said electronic device.

9. The electronic device of claim 7, wherein the locking part comprises a movement member configured to move said locking part inside said body part.

10. The electronic device of claim 7, wherein said locking part and said body part comprise guiding members configured to guide movement of the locking part inside said body part.

11. The electronic device of claim 10, wherein said guiding members comprise at least one rib.

12. The electronic device of claim 10, wherein said guiding members comprise at least one groove.

13. The electronic device of claim 7, wherein said locking part and said cover part comprise engagement members configured to engage said cover part with said locking part when said locking part is in said closed position.

14. The electronic device of claim 13, wherein said engagement members comprise at least one opening.

15. The electronic device of claim 13, wherein said guiding members comprise at least one hook like protrusion.

16. The electronic device of claim 7, wherein said movement of said locking part inside said body part is a linear movement along the length of the locking part.

17. The electronic device of claim 7, wherein said movement of said locking part inside said body part is a twisting movement about axis of the locking part.

18. A method, comprising:
mounting a locking part inside a body part of an electronic device, wherein said locking part is movable between an open position and a closed position inside the body part; and said locking part extends along most of the length of one edge of the body part;
fitting a cover part onto the body part while the locking part is in the open position, the cover part hiding the locking part inside the body part; and
moving said locking part into the closed position thereby engaging said cover part and coupling said cover part and said body part together.

19. The method of claim 18, wherein said moving comprises linearly moving said locking part along the length of said locking part.

20. The method of claim 18, wherein said moving of said locking part engages said cover part at a plurality of points along the length of said locking part.
